(19) United States
(12) Patent Application Publication
(10) Pub. No.: US 2025/0255186 A1
(43) Pub. Date: Aug. 7, 2025

(54) TACTILE SENSATION GENERATING DEVICE, TACTILE SENSATION GENERATING SYSTEM, AND METHOD FOR DRIVING TACTILE SENSATION GENERATING DEVICE

(71) Applicant: TAIYO YUDEN CO., LTD., Chuo-ku, Tokyo (JP)

(72) Inventors: Shigeo ISHII, Takasaki-shi (JP); Takeyuki FUKUSHIMA, Takasaki-shi (JP); Yukari SATO, Takasaki-shi (JP); Sumiaki KISHIMOTO, Takasaki-shi (JP); Hiroyuki SHIMIZU, Takasaki-shi (JP); Yuichi NAMIKAWA, Takasaki-shi (JP)

(21) Appl. No.: 18/855,990

(22) PCT Filed: Feb. 27, 2023
(86) PCT No.: PCT/JP2023/007110

§ 371 Date: Oct. 10, 2024

(30) Foreign Application Priority Data
Apr. 15, 2022 (JP) 2022-067536

(51) Int. Cl. H10N 30/20; H10N 30/87; H10N 30/88

(52) U.S. Cl. CPC H10N 30/20; H10N 30/87; H10N 30/88

(57) ABSTRACT

A tactile sensation generating device includes a housing and a piezoelectric actuator. The housing is constituted by a first member and a second member being joined together, and has a bar-like shape. The piezoelectric actuator includes piezoelectric layers made of piezoelectric material, positive internal electrodes provided in the piezoelectric layers, and negative internal electrodes provided in the piezoelectric layers and facing the positive internal electrodes, respectively, via the piezoelectric layers, respectively; expands/contracts along the direction perpendicular to the electrode faces of the positive internal electrodes and the negative internal electrodes upon voltage application between each positive internal electrode and each negative internal electrode; is interposed between the first member and the second member in an orientation that the direction perpendicular to the electrode faces corresponds to the longitudinal direction of the housing; and is pressed by the first member and the second member along the longitudinal direction.

### TECHNICAL FIELD

The present invention relates to a tactile sensation generating device that generates tactile sensations by means of vibration, a tactile sensation generating system, and a method for driving tactile sensation generating device.

### BACKGROUND ART

Various actuators are used in tactile function devices that present tactile sensations to the user. For example, their notification functions use eccentric motors, linear resonance actuators, and other electromagnetic actuators. Meanwhile, their force feedback functions use piezoelectric actuators in addition to these electromagnetic actuators.

Recent years have seen advancements in touch sensation technology, where arts of reproducing rough texture, smooth texture, and other forms of touch sensations have been developed (refer to Patent Literature 1, for example) in addition to notification functions. Moreover, LCD panels for mobile devices, etc., now require a different touch sensation surface for each area.

### BACKGROUND ART LITERATURE

### Patent Literature

Patent Literature 1: Japanese Patent Laid-open No. Hei 8-314369

### SUMMARY OF THE INVENTION

### Problems to be Solved by the Invention

Resin stylus pens are widely used as a conventional input means for tablet-type terminals, credit card processing terminals, and the like. However, there are many situations where the user feels it inconvenient to input information using a stylus pen or other pen-type member for reasons such as not knowing how much force to exert. Accordingly, the inventors of the present invention studied ways to improve the operating feel of an input device by generating various types of tactile sensations utilizing tactile technology.

In light of the aforementioned circumstance, an object of the present invention is to provide a tactile sensation generating device capable of presenting various types of tactile sensations based on tactile technology, a tactile sensation generating system, and a method for driving tactile sensation generating device.

### Means for Solving the Problems

To achieve the aforementioned object, the tactile sensation generating device pertaining to an embodiment of the present invention comprises a housing and a piezoelectric actuator.

The housing is constituted by a first member and a second member being joined together, and has a bar-like shape.

The piezoelectric actuator comprises piezoelectric layers made of piezoelectric material, positive internal electrodes provided in the piezoelectric layers, and negative internal electrodes provided in the piezoelectric layers and facing the positive internal electrodes via the piezoelectric layers; expands/contracts along the direction perpendicular to the electrode faces of the positive internal electrodes and the negative internal electrodes upon voltage application between the positive internal electrodes and the negative internal electrodes; is interposed between the first member and the second member in an orientation that the direction perpendicular to the electrode faces corresponds to the longitudinal direction of the housing; and is pressed by the first member and the second member along the longitudinal direction.

It may be that the first member and second member are joined to each other by screwing together, and the piezoelectric actuator is pressed along the longitudinal direction as a result of the screwing.

It may be that a concave part is provided in the face on the second-member side of the first member, the tactile sensation generating device is made of metal and further has a support placed inside the concave part, and the piezoelectric actuator is stored in the concave part and placed on the support.

It may be that the housing is pen-shaped,
the first member is a member that constitutes a pen shaft, and
the second member is a member that constitutes a pen tip.

It may be that the housing is pen-shaped,
and the first member and second member are members joined to each other to constitute a pen shaft.

It may be that the piezoelectric actuator comprises multiple piezoelectric actuator chips, and the multiple piezoelectric actuator chips are stacked in the longitudinal direction being the stacking direction.

It may be that the tactile sensation generating device further has a drive part that feeds to the positive internal electrodes and negative internal electrodes a drive signal having, when a signal wave of 2 Hz or higher but no higher than 50 Hz in frequency represents a modulation wave, a waveform resulting from amplitude-modulating a sine wave of 150 Hz or higher but no higher than 250 Hz in frequency by the modulation wave.

It may be that the housing has a prescribed resonance frequency, and
the tactile sensation generating device further has a drive part that feeds to the positive internal electrodes and negative internal electrodes a drive signal having, when a signal wave of 110 Hz or higher but no higher than 250 Hz in frequency represents a modulation wave, a waveform resulting from amplitude-modulating by the modulation wave a sine wave whose frequency corresponds to the resonance frequency.

It may be that the resonance frequency is 20 kHz or higher but no higher than 60 kHz.

It may be that the piezoelectric actuator comprises multiple piezoelectric actuator chips,
the piezoelectric actuator chips have a prescribed resonance frequency, and
the tactile sensation generating device further has a drive part that feeds to the positive internal electrodes and negative internal electrodes a drive signal having, when a signal wave of 110 Hz or higher but no higher than 250 Hz in frequency represents a modulation wave, a waveform resulting from amplitude-modulating by the modulation wave a sine wave whose frequency corresponds to the resonance frequency.

It may be that the resonance frequency is 30 kHz or higher but no higher than 110 kHz.

It may be that the tactile sensation generating device further has a drive part that feeds to the positive internal electrodes and negative internal electrodes a drive signal having, when a first low-frequency wave of 1 Hz or higher but lower than 60 Hz in frequency represents a first modulation wave and a waveform resulting from amplitude-modulating a second low-frequency wave of 50 Hz or higher but no higher than 300 Hz in frequency by the first modulation wave represents a second modulation wave, a waveform resulting from modulating a high-frequency wave of 20 kHz or higher but no higher than 110 kHz by the second modulation wave.

To achieve the aforementioned object, the tactile sensation generating system pertaining to an embodiment of the present invention comprises a tactile sensation generating device and a drive part.

The tactile sensation generating device comprises: a housing that is constituted by a first member and a second member being joined together, and has a bar-like shape; and a piezoelectric actuator that comprises piezoelectric layers made of piezoelectric material, positive internal electrodes provided in the piezoelectric layers, and negative internal electrodes provided in the piezoelectric layers and facing the positive internal electrodes via the piezoelectric layers; expands/contracts along the direction perpendicular to the electrode faces of the positive internal electrodes and the negative internal electrodes upon voltage application between the positive internal electrodes and the negative internal electrodes; is interposed between the first member and the second member in an orientation that the direction perpendicular to the electrode faces corresponds to the longitudinal direction of the housing; and is pressed by the first member and the second member along the longitudinal direction.

The drive part feeds a drive signal to the positive internal electrodes and negative internal electrodes.

To achieve the aforementioned object, the method for driving a tactile sensation generating device pertaining to an embodiment of the present invention comprises feeding a drive signal to positive internal electrodes and negative internal electrodes of a piezoelectric actuator installed in a housing that is constituted by a first member and a second member being joined together, and has a bar-like shape, where the piezoelectric actuator comprises piezoelectric layers made of piezoelectric material, positive internal electrodes provided in the piezoelectric layers, and negative internal electrodes provided in the piezoelectric layers and facing the positive internal electrodes via the piezoelectric layers; expands/contracts along the direction perpendicular to the electrode faces of the positive internal electrodes and the negative internal electrodes upon voltage application between the positive internal electrodes and the negative internal electrodes; is interposed between the first member and the second member in an orientation that the direction perpendicular to the electrode faces corresponds to the longitudinal direction of the housing; and is pressed by the first member and the second member along the longitudinal direction.

### Effects of the Invention

As described above, a tactile sensation generating device capable of presenting various types of touch sensations based on tactile technology, a tactile sensation generating system, and a method for driving a tactile sensation generating device, can be provided according to the present invention.

### BRIEF DESCRIPTION OF THE DRAWINGS

FIG. 1 An oblique view of the tactile sensation generating device pertaining to an embodiment of the present invention.

FIG. 2 An exploded oblique view of the tactile sensation generating device.

FIG. 3 A cross-sectional view of the tactile sensation generating device.

FIG. 4 A cross-sectional view of the first member of the housing of the tactile sensation generating device.

FIG. 5 A cross-sectional view of the second member of the housing of the tactile sensation generating device.

FIG. 6 A cross-sectional view of a piezoelectric actuator chip constituting the piezoelectric actuator of the tactile sensation generating device.

FIG. 7 A schematic view showing the thicknesses of piezoelectric layers in the piezoelectric actuator chip.

FIG. 8 A schematic view showing how the piezoelectric actuator chip vibrates.

FIG. 9 A schematic view showing how piezoelectric actuator chips stored in the housing of the tactile sensation generating device vibrate.

FIG. 10 A plan view of a piezoelectric actuator chip stored in the housing of the tactile sensation generating device.

FIG. 11 A schematic view showing the pressing structure of the piezoelectric actuator.

FIG. 12 A schematic view showing the pressing structure of the piezoelectric actuator.

FIG. 13 A schematic view showing operation of the tactile sensation generating device.

FIG. 14 A schematic view showing how the tactile sensation generating device vibrates.

FIG. 15 A waveform of an amplitude-modulated wave generated by the drive part of the tactile sensation generating device.

FIG. 16 An enlarged waveform of the amplitude-modulated wave in FIG. 15.

FIG. 17 A waveform of the amplitude-modulated wave (voltage waveform only) generated by the drive part of the tactile sensation generating device.

FIG. 18 An enlarged waveform of the amplitude-modulated wave in FIG. 17.

FIG. 19 A schematic view showing the amplitude of an amplitude-modulated wave.

FIG. 20 A waveform of an amplitude-modulated wave generated by the drive part of the tactile sensation generating device.

FIG. 21 A cross-sectional view of the tactile sensation generating device pertaining to a variation of the present invention.

FIG. 22 A cross-sectional view of the tactile sensation generating device pertaining to a variation of the present invention.

FIG. 23 A graph showing the resonance properties of the tactile sensation generating device pertaining to an example of the present invention.

FIG. 24 A graph showing the resonance properties of the tactile sensation generating device pertaining to an example of the present invention.

FIG. 25 An admittance circle of the piezoelectric actuator of the tactile sensation generating device pertaining to an example of the present invention.

FIG. 26 A circuit diagram of the equivalent circuit to the piezoelectric actuator of the tactile sensation generating device pertaining to an example of the present invention.

### MODE FOR CARRYING OUT THE INVENTION

The tactile sensation generating device pertaining to an embodiment of the present invention is explained.

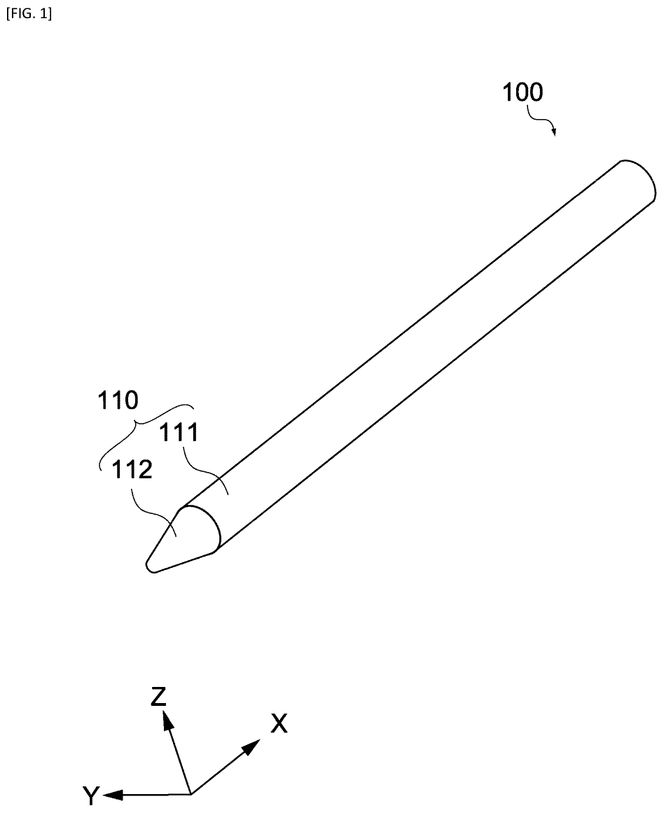

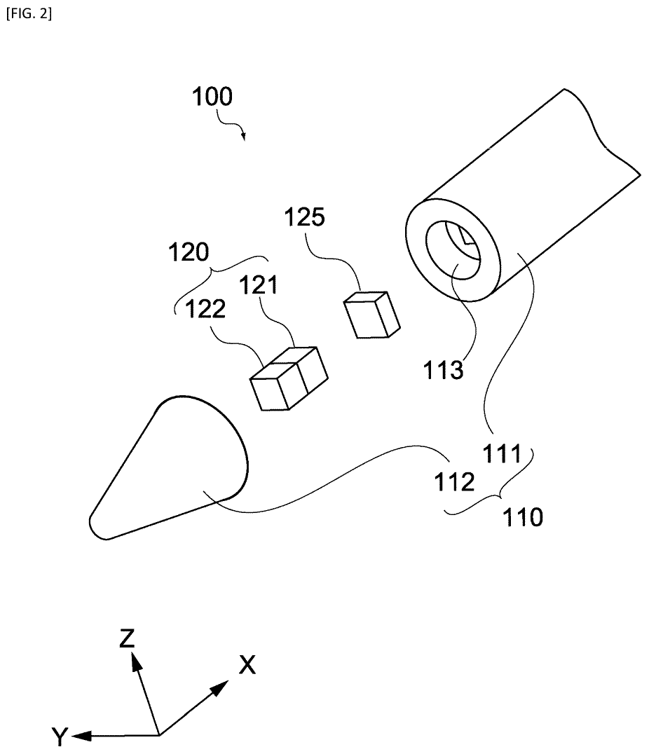

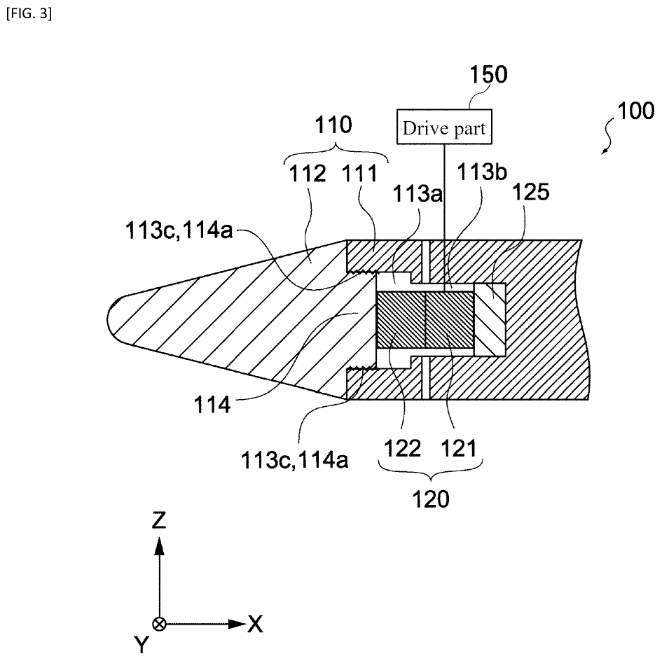

FIG. 1 is an oblique view of the tactile sensation generating device 100 pertaining to this embodiment, while FIG. 2 is an exploded oblique view of a part of the tactile sensation generating device 100. FIG. 3 is a cross-sectional view of a part of the tactile sensation generating device 100. As shown in FIG. 1, FIG. 2, and FIG. 3, the tactile sensation generating device 100 is a stylus pen-type device, being an input device for inputting information to a tablet-type terminal, smartphone display panel, or other target. As shown in FIG. 2, the tactile sensation generating device 100 comprises a housing 110 and a piezoelectric actuator 120. Hereinafter the longitudinal direction of the housing 110 is denoted as “X-direction,” one direction orthogonal to the X-direction is denoted as “Y-direction,” and the direction perpendicular to the X-direction and Z-direction is denoted as “Z-direction.”

The housing 110 is constituted by a first member 111 and a second member 112 being joined together, and has a pen-like shape. The first member 111 is a member that constitutes a pen shaft, having a bar-like shape extending along the X-direction. The second member 112 is a member that constitutes a pen tip, connected to one end of the first member 111 and having a conical shape whose diameter gradually decreases from the first member 111.

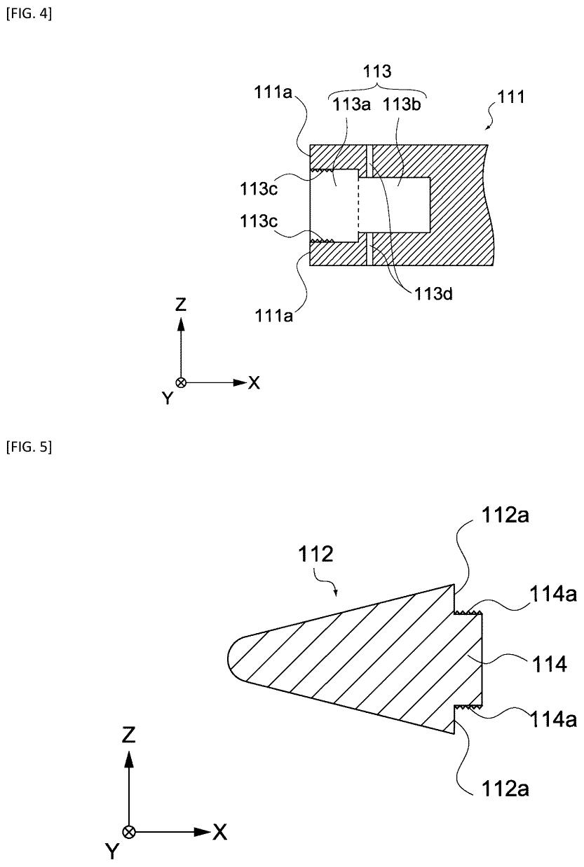

FIG. 4 is a cross-sectional view of a part on the second-member 112 side of the first member 111. As shown in FIG. 4, the face on the second-member 112 side of the first member 111 is denoted as “joint face 111a.” A concave part 113 is provided in the joint face 111a. The concave part 113 has a large-diameter part 113a on the second-member 112 side and a small-diameter part 113b on the opposite side of the second member 112. The large-diameter part 113a is a concave part of columnar shape with thread grooves 113c provided on the inner periphery. The small-diameter part 113b is a concave part of prism shape. Provided in the small-diameter part 113b are wiring holes 113d through which the wires of the piezoelectric actuator 120 are inserted. The material of the first member 111 is not specifically limited and can be metal, resin, or other material; however, a member made of PMMA (polymethyl methacrylate), PPS (polyphenylene sulfide), or other resin is suitable.

FIG. 5 is a cross-sectional view of the second member 112. As shown in FIG. 5, the face on the first-member 111 side of the second member 112 is denoted as “joint face 112a.” A convex part 114 is provided on the joint face 112a and thread ridges 114a are provided on the outer periphery of the convex part 114. The material of the second member 112 is not specifically limited and can be metal, resin, or other material; however, a member made of aluminum or other metal is suitable.

The piezoelectric actuator 120 vibrates to generate a tactile sensation on the tactile sensation generating device 100. As shown in FIG. 3, the piezoelectric actuator 120 is placed on a support 125 and stored in the concave part 113 (refer to FIG. 4). The support 125 is placed inside the small-diameter part 113b and made of stainless steel (Young's modulus: 1.93×10⁵ N/m) or other metal. The thickness of the support 125 is 2 mm, for example.

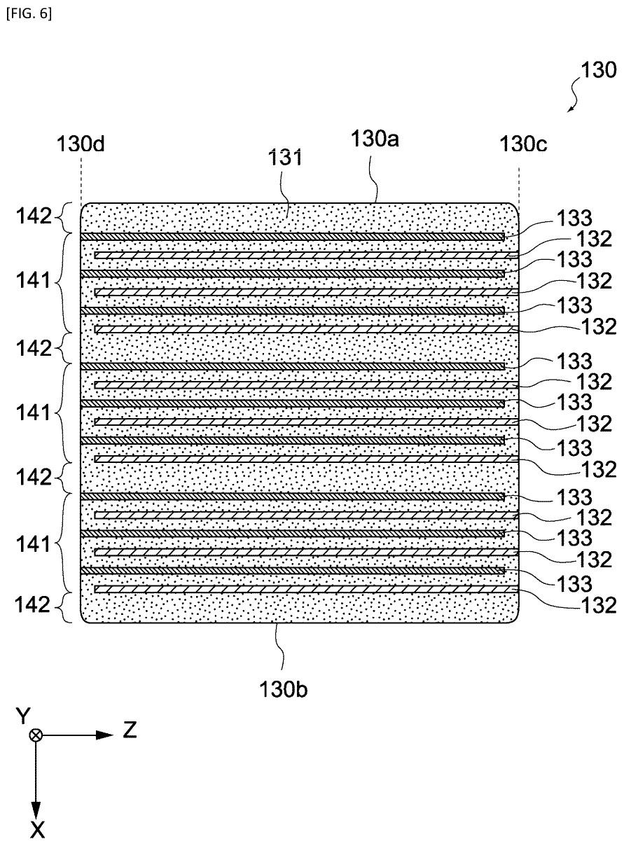

The piezoelectric actuator 120 is constituted by two piezoelectric actuator chips, including a first piezoelectric actuator chip 121 and a second piezoelectric actuator chip 122, stacked together as shown in FIG. 3. The first piezoelectric actuator chip 121 and second piezoelectric actuator chip 122 can be piezoelectric actuator chips having the same structure. FIG. 6 is a schematic representation of a piezoelectric actuator chip 130 capable of constituting the first piezoelectric actuator chip 121 and second piezoelectric actuator chip 122.

As shown in FIG. 6, the piezoelectric actuator chip 130 comprises piezoelectric layers 131, positive internal electrodes 132, and negative internal electrodes 133. Also, one principal face of the piezoelectric actuator chip 130 is denoted as “principal face 130a,” the principal face on the opposite side of the principal face 130a is denoted as “principal face 130b,” one side face is denoted as “side face 130c,” and the side face on the opposite side of the side face 130c is denoted as “side face 130d.” The piezoelectric layers 131 are made of a lead-based piezoelectric material or non-lead-based piezoelectric material. For the lead-based piezoelectric material, PZT (lead zirconate titanate: Pb(Zr,Ti)O₃), etc., can be utilized. For the non-lead-based piezoelectric material, a barium titanate-based material ((Ba,Ca)(Ti,Zr)O₃), bismuth-based material ((Bi_{1/2},Na_{1/2})TiO₃), alkali niobate-based material ((Li,Na,K)NbO₃), etc., can be utilized.

The positive internal electrodes 132 are made of a conductive material, and provided in the piezoelectric layers 131, and face the negative internal electrodes 133 via the piezoelectric layers 131. The positive internal electrodes 132 are shaped like flat plates and, when principal faces of the positive internal electrodes 132 are referred to as “electrode faces,” then the electrode faces are parallel to the principal faces 130a, 130b. The positive internal electrodes 132 are exposed to the side face 130c and separated from the side face 130d, as shown in FIG. 6. The positive internal electrodes 132 are abutted to, and electrically connected with, a positive external electrode formed on the side face 130c but not illustrated.

The negative internal electrodes 133 are made of a conductive material, and provided between the piezoelectric layers 131, and face the positive internal electrodes 132 via the piezoelectric layers 131. The negative internal electrodes 133 are shaped like flat plates and, when principal faces of the negative internal electrodes 133 are referred to as “electrode faces,” then the electrode faces are parallel to the principal faces 130a, 130b. The negative internal electrodes 133 are exposed to the side face 130d and separated from the side face 130c, as shown in FIG. 6. The negative internal electrodes 133 are abutted to, and electrically connected with, a negative external electrode formed on the side face 130d but not illustrated.

As shown in FIG. 6, the piezoelectric actuator chip 130 has blocks 141 and buffer layers 142. The blocks 141 each include multiple positive internal electrodes 132 and multiple negative internal electrodes 133, and three blocks 141 are provided in the piezoelectric actuator chip 130. The numbers of positive internal electrodes 132 and negative internal electrodes 133 included in each block 141 are not specifically limited, but there can be 50 layers in total. This means that the piezoelectric actuator chip 130 can have a total of 150 layers of positive internal electrodes 132 and negative internal electrodes 133 across three blocks 141. It should be noted that, in FIG. 6, each block 141 is illustrated to include three layers each of positive internal electrodes 132 and negative internal electrodes 133 as a matter of convenience.

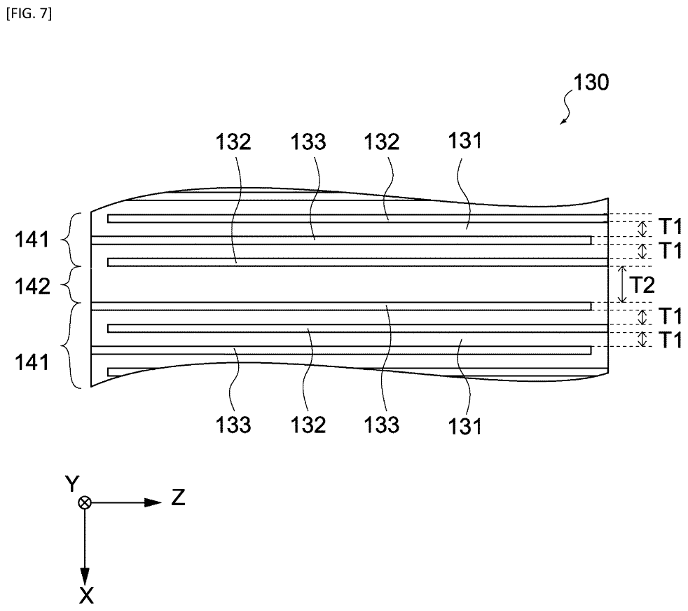

The buffer layers 142 are provided between the blocks 141 and on the principal-face 130a side and principal-face 130b side of the piezoelectric actuator chip 130. The buffer layers 142 are constituted by thick piezoelectric layers 131. FIG. 7 is a schematic view showing the thickness of a buffer layer 142. As shown in FIG. 7, the thickness of each piezoelectric layer 131 between a positive internal electrode 132 and a negative internal electrode 133 in each block 141 is denoted as “thickness T1,” while the thickness of the piezoelectric layer 131 in the buffer layer 142 is denoted as “thickness T2.” The thickness T2 is greater than the thickness T1, or suitably equal to or greater than twice the thickness T1; for example, the thickness T1 can be 18 μm, and thickness T2, 36 μm.

The piezoelectric actuator chip 130 can be formed by using a conductive paste to form positive internal electrodes 132 or negative internal electrodes 133 on piezoelectric plates that will become piezoelectric layers 131, and then stacking the piezoelectric plates and sintering the stacked plates. It should be noted that, if a large number of piezoelectric plates are to be stacked, a sintered body can be formed for each block 141, followed by layering and pressure-bonding of all blocks 141, to form the piezoelectric actuator chip 130. At this time, using buffer layers 142 to reinforce adhesion between the blocks 141 while mitigating the internal stress during pressure bonding, allows for formation of a piezoelectric actuator chip 130 offering excellent properties. It should be noted that the number of blocks 141 is not limited to three, and it may be two or less, or four or more.

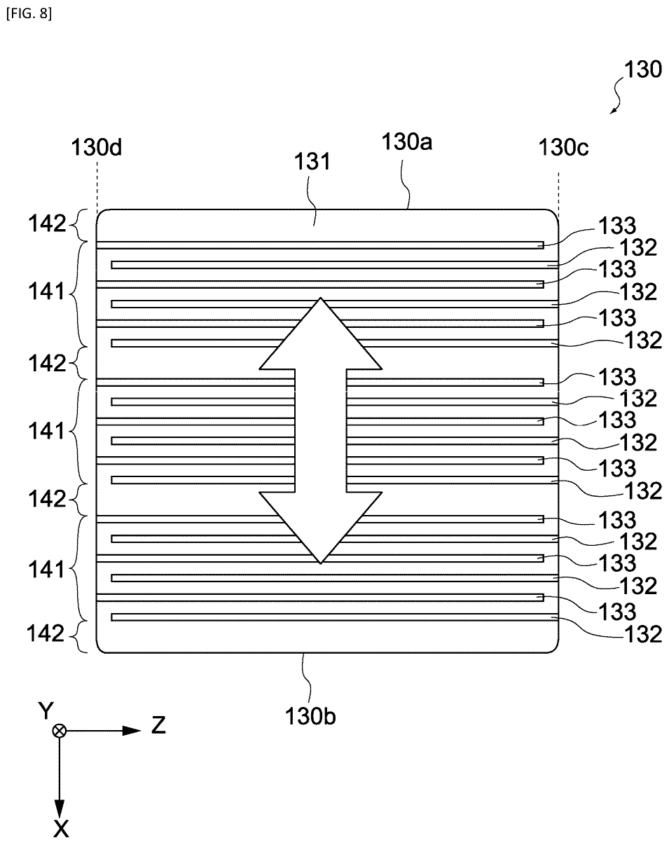

The piezoelectric actuator chip 130 has the following constitution. FIG. 8 is a schematic view showing how the piezoelectric actuator chip 130 vibrates. When voltage is applied between the positive internal electrodes 132 and negative internal electrodes 133, the inverse piezoelectric effect at the piezoelectric layers 131 causes the piezoelectric actuator chip 130 to expand/contract in a direction perpendicular to the electrode faces of the positive internal electrodes 132 and negative internal electrodes 133 (arrows in the figure), and vibrate in this direction being the amplitude direction. Such vibration is called “d33 mode.” The piezoelectric actuator chip 130 that operates in the d33 mode can also support unipolar drive when a DC component is added, which serves as a countermeasure against polarization deterioration and also prevents occurrence of abnormal noises.

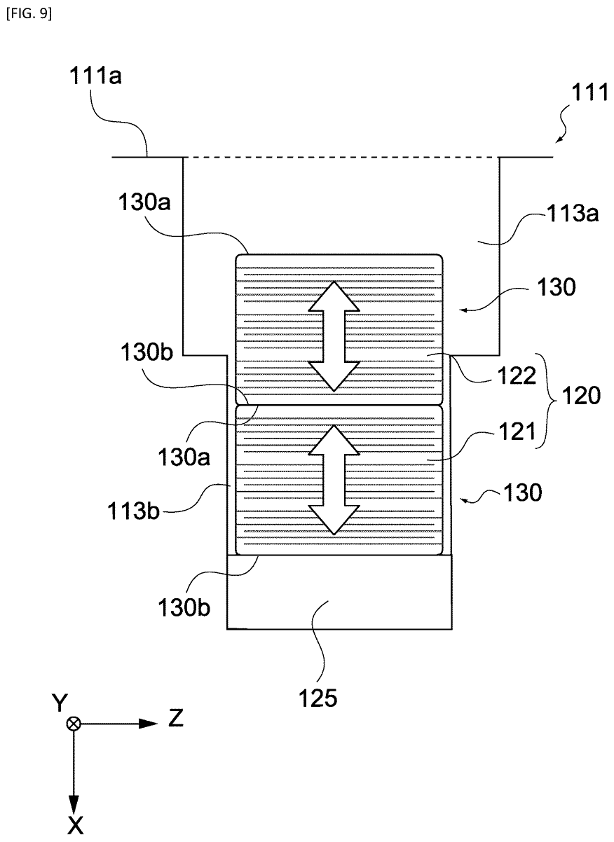

As described above, the piezoelectric actuator 120 comprises the first piezoelectric actuator chip 121 and second piezoelectric actuator chip 122, and the first piezoelectric actuator chip 121 and second piezoelectric actuator chip 122 each have the constitution of the piezoelectric actuator chip 130. FIG. 9 is a schematic view showing the orientation of the piezoelectric actuator chips 130 that constitute the piezoelectric actuator 120.

As shown in FIG. 9, the two piezoelectric actuator chips 130, oriented in such a way that their vibrating direction (arrows in the figure) corresponds to the longitudinal direction (X-direction) of the housing 110, are stacked in this direction (X-direction) being the stacking direction and stored in the concave part 113. Accordingly, the piezoelectric actuator 120 is a piezoelectric actuator that vibrates in the d33 mode (hereinafter “d33 piezoelectric actuator”). Since the displacement of the d33 piezoelectric actuator is expressed by (Formula 1) below, a multistage piezoelectric actuator 120 having a larger displacement can be constituted by stacking two piezoelectric actuator chips 130.

$$Δ z = d 33 \cdot v \cdot n \qquad ( Formula 1 )$$

It should be noted that Δz represents the displacement, d33 represents the material constant of the piezoelectric layers 131, v represents the impressed voltage, and n represents the number of stacked piezoelectric layers.

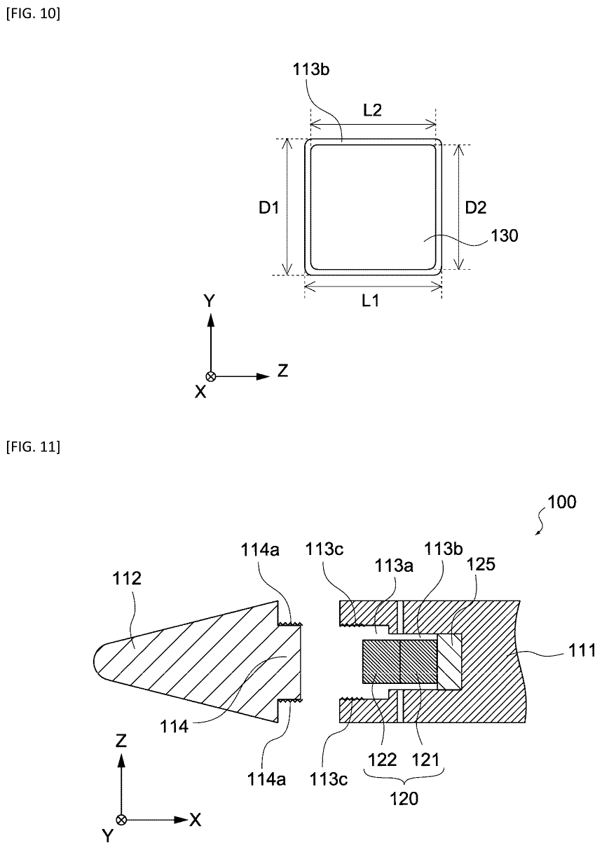

FIG. 10 is a plan view showing the small-diameter part 113b and piezoelectric actuator chip 130. As shown in FIG. 10, the piezoelectric actuator chip 130 is smaller than the small-diameter part 113b, where suitably the size of the piezoelectric actuator chip 130 is such that a gap is formed along the small-diameter part 113b. As shown in FIG. 10, when the length (X-direction) and width (Y-direction) of the small-diameter part 113b are referred to as “length L1” and “width D1,” respectively, and the length (X-direction) and width (Y-direction) of the piezoelectric actuator chip 130 are referred to as “length L2” and “width D2,” respectively, the length L1 and width D1 can both be 4 mm, while the length L2 and width D2 can both be 3.5 mm, as an example.

The piezoelectric actuator 120 has the aforementioned constitution. It should be noted that, although the piezoelectric actuator 120 was described as being constituted by two piezoelectric actuator chips 130, it may be constituted by one or three or more piezoelectric actuator chips 130. Also, the piezoelectric actuator 120 may have other constitutions so long as it is a d33 piezoelectric actuator whose vibrating direction corresponds to the longitudinal direction (X-direction) of the housing 110.

It can be that the first piezoelectric actuator chip 121 and second piezoelectric actuator chip 122 are fixed with an adhesive, while the first piezoelectric actuator chip 121 and support 125 are also fixed with an adhesive. Additionally, the first piezoelectric actuator chip 121 and second piezoelectric actuator chip 122 may be stored in the concave part 113 and then fixed with a sealant to be filled in the concave part 113. The aforementioned adhesive and sealant are epoxy resins, for example.

### [Pressing Structure of Piezoelectric Actuator]

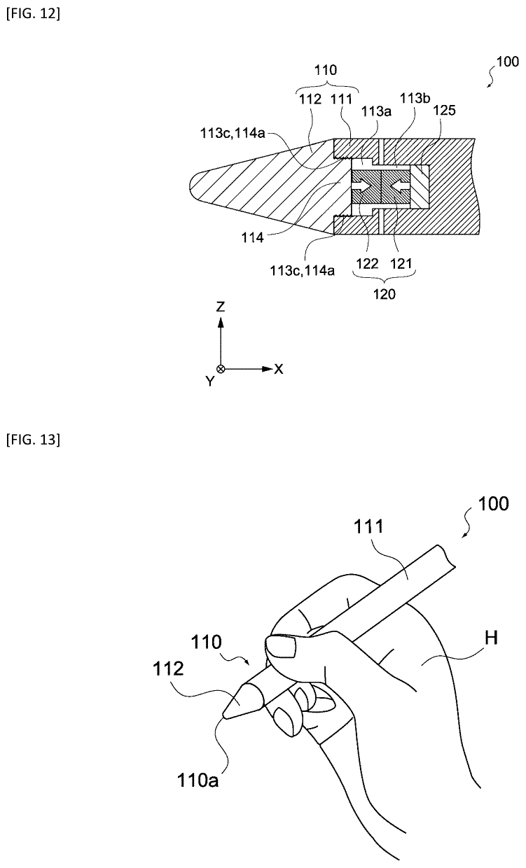

The pressing structure of the piezoelectric actuator 120 in the tactile sensation generating device 100 is explained. FIG. 11 and FIG. 12 are schematic views showing the pressing structure of the piezoelectric actuator 120. As shown in FIG. 11, the piezoelectric actuator 120 is placed on the support 125 and stored in the concave part 113.

In this condition, as shown in FIG. 12, the second member 112 is abutted to the first member 111 and turned around the longitudinal direction (X-direction) of the housing 110 serving as the axis of rotation. As a result, the thread ridges 114a engage with the thread grooves 113c and the first member 111 and second member 112 are joined, i.e., the first member 111 and second member 112 are screwed together. This turning action causes the convex part 114 to abut to the piezoelectric actuator 120, and the piezoelectric actuator 120 is pressed by the convex part 114 and support 125. In FIG. 12, the pressing forces received by the piezoelectric actuator 120 are shown by the arrows.

### [Operation and Effects of Input Device]

FIG. 13 is a schematic view showing operation of the tactile sensation generating device 100. As shown in FIG. 13, the user can hold the tactile sensation generating device 100 in his/her hand H. In this condition, the user can move the input device with its tip 110a contacting the target. The target receives an operating input according to the contacting and movement of the tip 110a and executes a shape drawing process, etc.

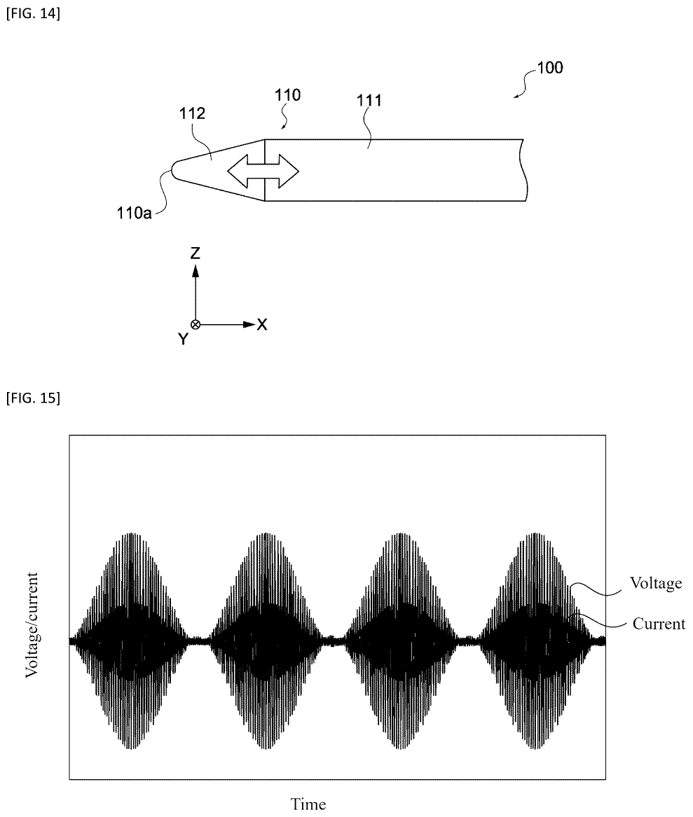

As described above, the piezoelectric actuator 120 is driven to generate vibration in the tactile sensation generating device 100. FIG. 14 is a schematic view showing, with arrows, the direction of the vibration generated in the tactile sensation generating device 100. As shown in FIG. 14, in the tactile sensation generating device 100, the piezoelectric actuator 120 is driven to cause the piezoelectric actuator 120 to expand/contract along the longitudinal direction (X-direction) of the housing 110 and vibrate in the d33 mode in this direction (X-direction) being the amplitude direction.

Because the piezoelectric actuator 120 is provided in the tactile sensation generating device 100, the tactile sensation generating device 100 can present realistic expressions of tactile sensations to the user. To be specific, the tactile sensation generating device 100 can express different pen types such as pencil, crayon, and brush using vibrations, or express different target types such as Japanese paper, Western paper, and wood-grain material using vibrations. At this time, the vibrating direction (X-direction) of the piezoelectric actuator 120 corresponds to the contacting direction (X-direction) of the tip 110a to the target, which means that the ability of the piezoelectric actuator 120 to generate vibration in this direction (X-direction) can be utilized in an advantageous manner. Also, a d33 piezoelectric actuator exhibits the greatest durability against the vibrating direction, allowing for durability improvement of the piezoelectric actuator 120.

Also, as described above, in the tactile sensation generating device 100, the piezoelectric actuator 120 is sandwiched between the first member 111 and second member 112 and pressed along the same direction as the vibrating direction (X-direction). This increases the mechanical Q factor of the tactile sensation generating device 100, and strong vibration is obtained as a result (refer to “Example”). The mechanical Q factor represents the degree of dispersion of vibrational energy, where the higher the mechanical Q factor, the lower the dispersion of vibrational energy becomes. This means that, in the tactile sensation generating device 100, a non-lead-based piezoelectric material or other material having low piezoelectric properties can also be utilized as the material for the piezoelectric layers 131 (refer to FIG. 6).

Furthermore, the piezoelectric actuator 120 has no mechanically driven part such as motor and is instead constituted by piezoelectric actuator chips 130 that are compact, lightweight, and low in power consumption, which allows for reduction in the footprint and power consumption of the piezoelectric actuator 120. Additionally, because the piezoelectric actuator 120 is highly responsive, the tactile sensation generating device 100 can express tactile sensations in a manner taking advantage of this high responsiveness.

In addition, the tactile sensation generating device 100 can control whether or not the user will perceive any tactile sensation according to the mode of contact of the tactile sensation generating device 100 with respect to the target, by feeding to the piezoelectric actuator 120 drive signals that are explained below. To be specific, causing its tip 110a to contact the target while the piezoelectric actuator 120 is being driven generates a tactile sensation in the tactile sensation generating device 100, and the tactile sensation will stop once the tip 110a is separated from the target. This eliminates the need to use a pressure-sensitive sensor, impact sensor, image recognition, etc., to detect that the tactile sensation generating device 100 has contacted the target and allows for automatic switching of tactile sensations according to the mode of contact of the tactile sensation generating device 100 with respect to the target.

It should be noted that the tactile sensation generating device 100, when its second member 112 is made of metal or other conductive material, can be utilized for inputting information to a capacitive touch panel. If the tactile sensation generating device 100 is used for inputting information to a pressure-sensitive touch panel, etc., on the other hand, the second member 112 may be made of an insulating material.

### [Drive Signals]

Drive signals output to the piezoelectric actuators 120 are explained. These drive signals are voltage waveforms applied between the positive internal electrodes 132 and negative internal electrodes 133 of the piezoelectric actuator chip 130 as described above. It should be noted that these drive signals may be fed to the piezoelectric actuator 120 from a drive part 150 (refer to FIG. 3) installed in the tactile sensation generating device 100, or they may be fed to the piezoelectric actuator 120 via wireless communication, etc., from a drive part 150 installed in a device different from the tactile sensation generating device 100. The tactile sensation generating device 100 and drive part 150 may be combined as a “tactile sensation generating system.”

### (Drive Signal 1)

A drive signal output by the drive part 150 to the piezoelectric actuator 120 can be one having, when a signal wave of 2 Hz or higher but no higher than 50 Hz in frequency represents a modulation wave, a waveform resulting from amplitude-modulating a sine wave of 150 Hz or higher but no higher than 250 Hz in frequency by the modulation wave. Here, a vibration at 150 Hz or higher but no higher than 250 Hz is a vibration that can be sensitively perceived by Pacinian corpuscles, etc., that are receptors in the human skin.

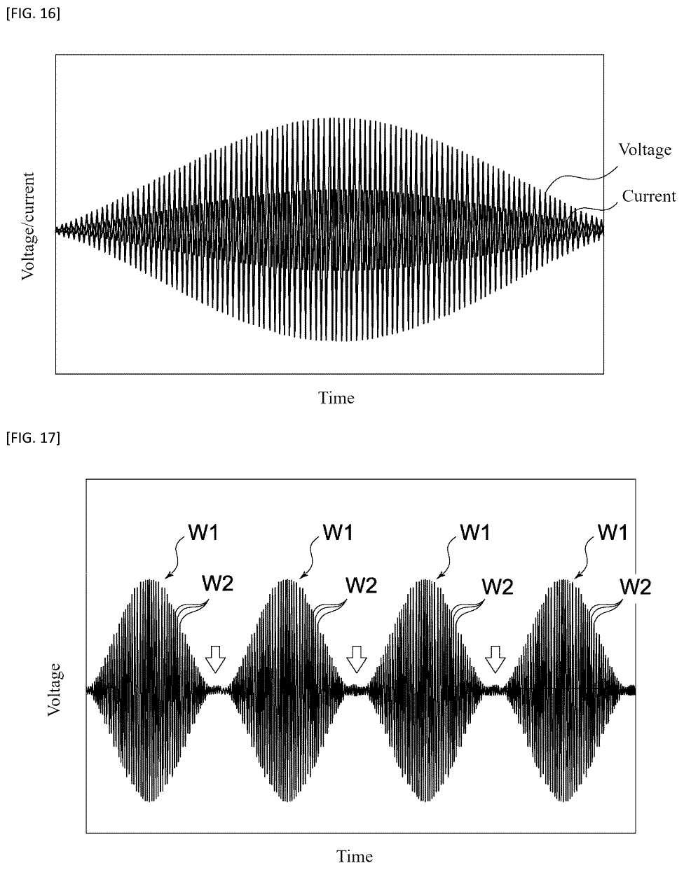

FIG. 15 shows a voltage waveform and a current waveform, each having, when a sine wave having a first frequency represents a modulation wave, the waveform of an amplitude-modulated wave being a sine wave having a second frequency that has been amplitude-modulated by the modulation wave. FIG. 16 is an enlarged view of FIG. 15. When the voltage waveform shown in FIG. 15 is applied to the piezoelectric actuator 120 from the drive part 150 as a drive signal, a current having the current waveform shown in FIG. 15 flows.

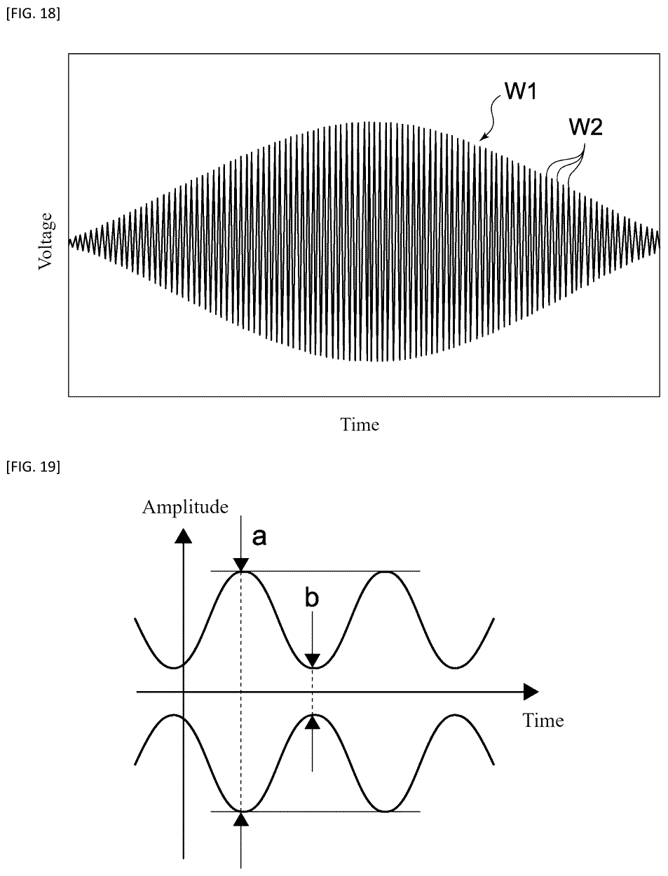

FIG. 17 shows only the voltage waveform in FIG. 15, while FIG. 18 shows only the voltage waveform in FIG. 16. In FIG. 17 and FIG. 18, the wave of longer wavelength denoted by W1 represents the sine wave having the first frequency, while the wave of shorter wavelength denoted by W2 represents the sine wave having the second frequency. Hereinafter the sine wave having the first frequency is denoted as “first sine wave W1,” while the sine wave having the second frequency is denoted as “second sine wave W2.”

In the waveform shown in FIG. 17 and FIG. 18, the first sine wave W1 is formed by an amplitude change to the second sine wave W2, i.e., the waveform shown in FIG. 17 and FIG. 18 is an amplitude-modulated wave based on the second sine wave W2 serving as a carrier wave and the first sine wave W1 serving as a modulation wave. The drive part 150 can generate, and apply to the piezoelectric actuator 120, a drive signal having the waveform of an amplitude-modulated wave based on the second sine wave W2 of 150 Hz or higher but no higher than 250 Hz in frequency serving as a carrier wave and the first sine wave W1 of 2 Hz or higher but no higher than 50 Hz in frequency serving as a modulation wave.

FIG. 19 is a schematic view showing the relationship between the waveform of an amplitude-modulated wave and the voltage gain. As shown in FIG. 19, when the “peak” amplitude of the amplitude-modulated wave is denoted as “amplitude a” and the “valley” amplitude as “amplitude b,” the degree of modulation m is expressed by (Formula 2) below. As shown by (Formula 2) below, the smaller the amplitude b with respect to the amplitude a, the greater the degree of modulation m becomes.

$$M = ( a - b ) / ( a + b ) \qquad ( Formula 2 )$$

Similarly in FIG. 17, as shown with white arrows in FIG. 17, increasing the voltage gain of the first sine wave W1 makes the “valley” of the first sine wave W1 deeper, while bringing the voltage gain of the first sine wave W1 to 0 dB results in the lowest “valley” amplitude. Also, decreasing the voltage gain of the first sine wave W1 makes the “valley” of the first sine wave W1 shallower, and its amplitude greater. Lowering the voltage gain of the first sine wave W1 further brings the “valley” amplitude b of the first sine wave W1 equal to the “peak” amplitude, at which point a “valley” is no longer formed. In this embodiment, the degree of modulation m is adjusted in a range of 50% or higher but no higher than 100%, and a gap in amplitude modulation can be utilized for expression of tactile sensation. Additionally, the current consumption is reduced where the voltage is squeezed, which allows for reduction in power consumption. It should be noted that, while the above explanation used the first sine wave W1 and second sine wave W2 to explain the amplitude-modulated wave, the amplitude-modulated wave may be formed using waves other than sine waves.

The drive part 150 feeds to the piezoelectric actuator 120 a drive signal having, when a signal wave of 2 Hz or higher but no higher than 50 Hz in frequency represents a modulation wave, a waveform resulting from amplitude-modulating a sine wave of 150 Hz or higher but no higher than 250 Hz in frequency by the modulation wave. The result is that, as he/she moves the tactile sensation generating device 100 with its tip 110a (refer to FIG. 13) contacting the target, the user can perceive various types of vibration-based tactile sensations from the tactile sensation generating device 100. Furthermore, these tactile sensations can be adjusted according to the frequency of the modulation wave, which allows the tactile sensation generating device 100 to create different types of writing implements such as pencil, crayon, and brush, as well as target materials such as Western paper, Japanese paper, and wood-grain material.

### (Drive Signal 2)

A drive signal output by the drive part 150 to the piezoelectric actuator 120 can be one having, when a signal wave of 110 Hz or higher but no higher than 250 Hz in frequency represents a modulation wave, a waveform resulting from amplitude-modulating by the modulation wave a sine wave whose frequency corresponds to the resonance frequency of the housing 110 or piezoelectric actuator chip 130. Here, a vibration at 110 Hz or higher but no higher than 250 Hz is a vibration that can be sensitively perceived by Pacinian corpuscles, etc., that are receptors in the human skin. The resonance frequency of the housing 110 is 20 kHz or higher but no higher than 60 kHz, while the resonance frequency of the piezoelectric actuator chip 130 is 30 kHz or higher but no higher than 110 kHz.

In the aforementioned waveform shown in FIG. 17 and FIG. 18, the first sine wave W1 is formed by an amplitude change to the second sine wave W2, i.e., the waveform shown in FIG. 17 and FIG. 18 is an amplitude-modulated wave based on the second sine wave W2 serving as a carrier wave and the first sine wave W1 serving as a modulation wave. The drive part 150 can generate, and apply to the piezoelectric actuator 120, a drive signal having the waveform of an amplitude-modulated wave based on the second sine wave W2 having the resonance frequency of the housing 110 or piezoelectric actuator chip 130 serving as a carrier wave and the first sine wave W1 of 110 Hz or higher but no higher than 250 Hz in frequency serving as a modulation wave.

The degree of modulation m (refer to (Formula 2) above) is adjusted in a range of 50% or higher but no higher than 100%, and a gap in amplitude modulation can be utilized for expression of tactile sensation. Additionally, the current consumption is reduced where the voltage is squeezed, which allows for reduction in power consumption. It should be noted that, while the above explanation used the first sine wave W1 and second sine wave W2 to explain the amplitude-modulated wave, the amplitude-modulated wave may be formed using waves other than sine waves.

The drive part 150 feeds to the piezoelectric actuator 120 a drive signal having, when a signal wave of 110 Hz or higher but no higher than 250 Hz in frequency represents a modulation waveform, a waveform resulting from amplitude-modulating by the modulation wave a sine wave whose frequency corresponds to the resonance frequency of the housing 110 or piezoelectric actuator chip 130. The result is that, as he/she moves the tactile sensation generating device 100 with its tip 110a (refer to FIG. 13) contacting the target, the user can perceive a squeeze effect (sense of lifting due to vibration) on the tactile sensation generating device 100. Also, when the tip 110a separates from the target, the user no longer perceives the squeeze effect on the tactile sensation generating device 100. This allows the tactile sensation generating device 100 to switch the tactile sensation to be presented to the user according to whether or not its tip 110a is contacting the target, where this switching does not require detection of whether the tactile sensation generating device 100 is contacting the target.

### (Drive Signal 3)

A drive signal output by the drive part 150 to the piezoelectric actuator 120 can be one having, when a first low-frequency wave of 1 Hz or higher but lower than 60 Hz in frequency represents a first modulation wave and a waveform resulting from amplitude-modulating a second low-frequency wave of 50 Hz or higher but no higher than 300 Hz in frequency by the first modulation wave represents a second modulation wave, a waveform resulting from amplitude-modulating a high-frequency wave of 20 kHz or higher but no higher than 110 kHz in frequency by the second modulation wave. Here, a vibration at 1 Hz or higher but no higher than 60 Hz is a vibration that can be sensitively perceived by Meissner corpuscles, etc., that are receptors in the human skin.

In the aforementioned waveform shown in FIG. 17 and FIG. 18, the first sine wave W1 is formed by an amplitude change to the second sine wave W2, i.e., the waveform shown in FIG. 17 and FIG. 18 is an amplitude-modulated wave resulting, when the second sine wave W2 represents a carrier wave and the first sine wave W1 represents a modulation wave, from amplitude-modulating the second sine wave W2 by the first sine wave W1. Hereinafter the first sine wave W1 is denoted as “first modulation wave” and the amplitude-modulated wave, as “second modulation wave.” The degree of modulation m of amplitude modulation (refer to (Formula 2) above) is adjusted in a range of 50% or higher but no higher than 100%, and a gap in amplitude modulation can be utilized for expression of tactile sensation. Additionally, the current consumption is reduced where the voltage is squeezed, which allows for reduction in power consumption.

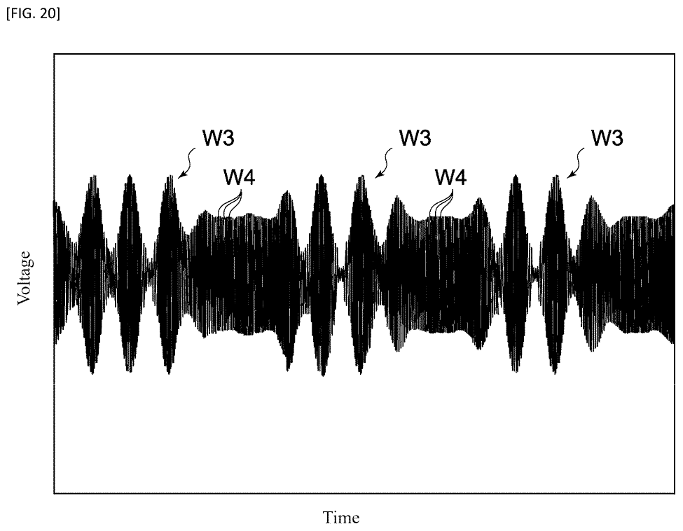

Furthermore, the drive part 150 generates an amplitude-modulated wave from a high-frequency wave and a second modulation wave. The high-frequency wave is a sine wave of 20 kHz or higher but no higher than 110 kHz in frequency. FIG. 20 is an example of a drive signal wave based on amplitude modulation, showing a waveform resulting from amplitude-modulating a high-frequency wave by a second modulation wave. In FIG. 20, the wave of shorter wavelength denoted by W4 represents an amplitude-modulated high-frequency wave, while the wave of longer wavelength denoted by W3 represents a second modulation wave formed by an amplitude change to the high-frequency wave W4. In other words, the waveform shown in FIG. 20 is an amplitude-modulated wave based on the high-frequency wave W4 serving as a carrier wave and the second modulation wave W3 serving as a modulation wave.

The drive part 150 feeds to the piezoelectric actuator 120 a drive signal having, when a first low-frequency wave of 1 Hz or higher but lower than 60 Hz in frequency represents a first modulation wave and a waveform resulting from amplitude-modulating a second low-frequency wave of 50 Hz or higher but no higher than 300 Hz in frequency by the first modulation wave represents a second modulation wave, a waveform resulting from modulating a high-frequency wave of 20 kHz or higher but no higher than 110 kHz in frequency by the second modulation wave. This adds fine micro-vibration expressions to the squeeze effect from modulated driving to enable more realistic tactile sensations.

### Variations

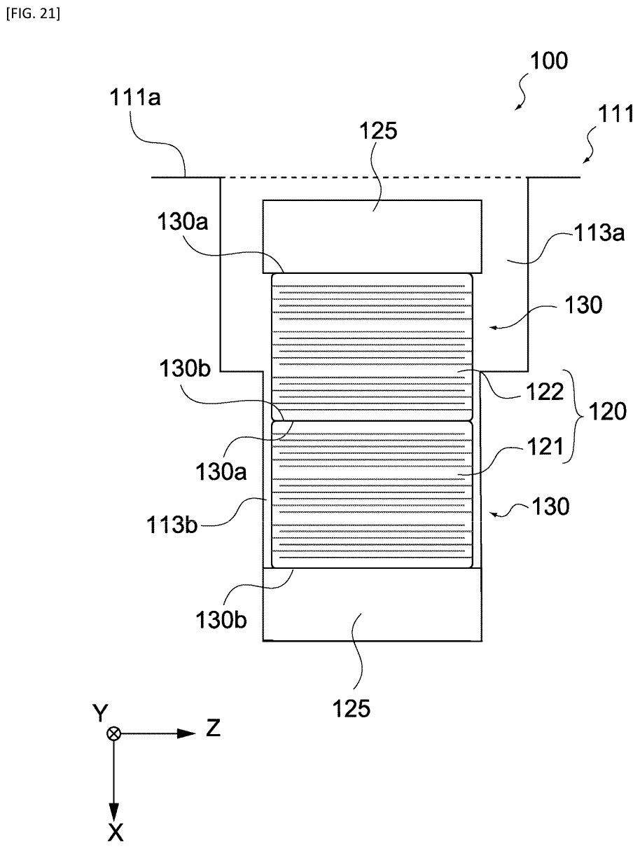

While the tactile sensation generating device 100 was described as having a support 125 placed on one side of the piezoelectric actuator 120 as shown in FIG. 9, supports 125 can be placed on both sides of the piezoelectric actuator 120. FIG. 21 is a schematic view of the tactile sensation generating device pertaining to a variation. As shown in FIG. 21, placing supports 125 on both exteriors of the piezoelectric actuator 120 causes the piezoelectric actuator 120 to be pressed by the supports 125 on both sides from the joining of the first member 111 and second member 112. In this case, the mass element, to which the vibration is directly transmitted by the piezoelectric actuator 120, increases, which in turn strengthens the vibration transmission, and thereby amplifies the vibration, attributable to the low-frequency amplitude-modulated driving (“drive signal 1” above).

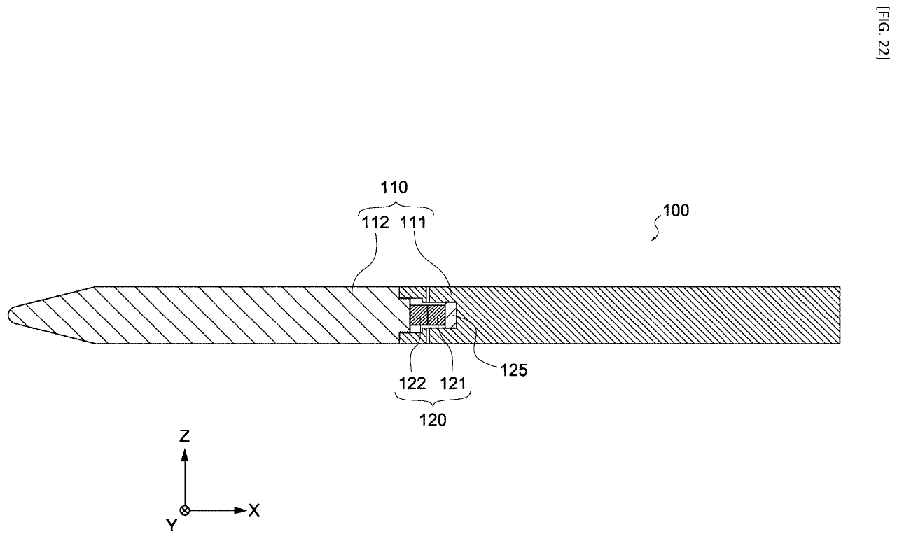

While the tactile sensation generating device 100 was explained as having the first member 111 being a member that constitutes a pen shaft and the second member 112 being a member that constitutes a pen tip, it is not limited to the foregoing. FIG. 22 is a cross-sectional view of the tactile sensation generating device 100 pertaining to another variation. As shown in FIG. 22, the first member 111 and second member 112 may constitute a pen shaft when joined together. According to this constitution, the piezoelectric actuator 120 can still generate strong vibration, being sandwiched between the first member 111 and second member 112 in such orientation that its vibrating direction corresponds to the longitudinal direction (X-direction) of the housing 110 and pressed along this direction (X-direction).

Also, the present invention can be applied to a device having a bar-like shape, other than an input device, to constitute a tactile sensation generating device, realizing a tactile sensation generating device that generates strong vibration when its piezoelectric actuator is pressed along the longitudinal direction of the device's housing as described above. For example, the present invention can be applied to scalers, facial massaging devices, peelers, temples of eyeglasses, nose pads of eyeglasses, walking sticks, chopsticks, and the like.

Furthermore, the tactile sensation generating device 100 can have sound signals applied to it as drive signals so that sounds will be generated from the tactile sensation generating device 100. The user can enjoy music by holding the housing 110 to the base of his/her ear, and when the housing 110 is held to a desk, acrylic board, wall, or other contact target to allow the vertical vibration of the housing 110 to be transmitted to the contact target, the contact target can be utilized as a speaker vibration plate for use in acoustic applications. To illustrate this point in an example, the present invention can be utilized when an acrylic partition board for COVID protection is to be used as a speaker. Also, the present invention can be used in contact with a tablet or direction board as a voice guide. In this case, plates made of stainless steel or other metal may be placed over the side faces 130c, 130d of the piezoelectric actuator chip 130.

### EXAMPLES

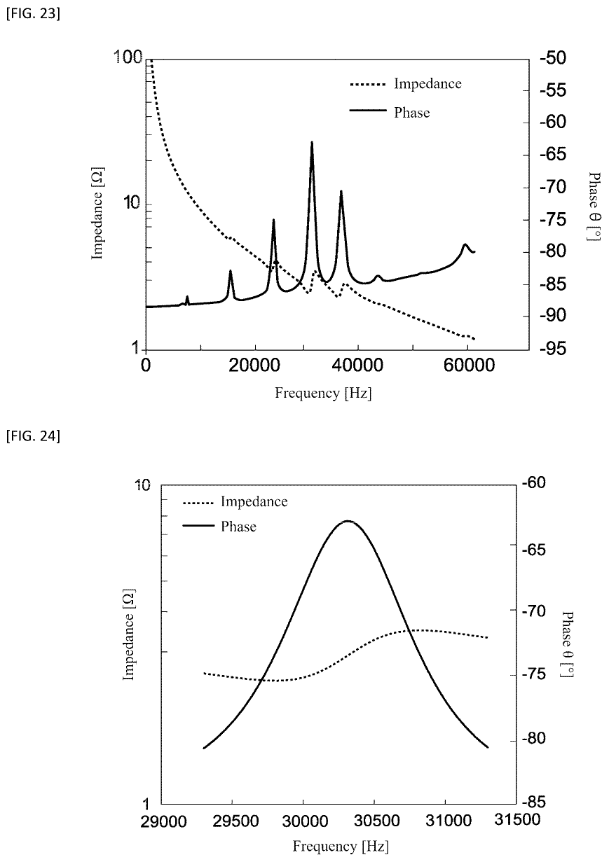

An input device having the constitution pertaining to the aforementioned embodiment was produced and its resonance properties were measured with an impedance analyzer. FIG. 23 and FIG. 24 are graphs showing the measured resonance properties, where FIG. 24 is an enlarged view of a part of FIG. 23. As shown in FIG. 23 and FIG. 24, the input device pertaining to the present invention has steep phase peaks. This is due to a high mechanical Q factor. Also, the resonance frequency of the input device registered 30.3 kHz. The resonance frequency was predicted to trend at a high level due to the pressing of the piezoelectric actuator by the first member and second member, but it didn't in reality. Presumably this has something to do with the support made of stainless steel.

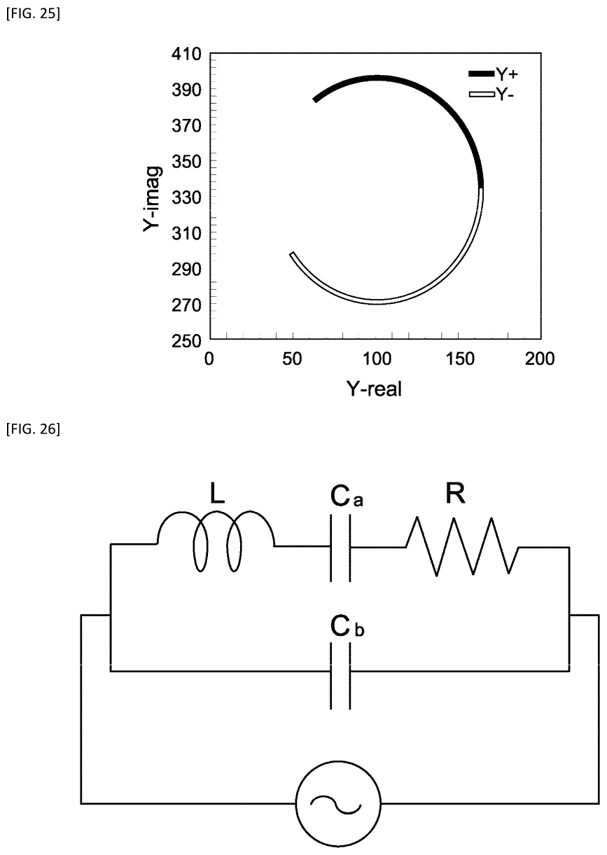

Additionally, an admittance circle was generated from the measured results to form an equivalent circuit to the piezoelectric actuator. FIG. 25 shows the generated admittance circle. FIG. 26 is a circuit diagram of the equivalent circuit having the equivalent resistance R, equivalent inductance L, equivalent capacity Ca, and breaking capacity C_{b}. The resonance frequency f₀, mechanical Q factor, and mechanical coupling coefficient Kᵥₙ of the piezoelectric actuator are calculated by Formulas (3) to (5) below.

$$\begin{matrix}[ Math . 1 ] & \\ {f}_{0} = \frac{1}{2 π} \sqrt{\frac{1}{( L \times {C}_{a} )}} & ( Formula 3 )\end{matrix}$$

$$\begin{matrix}[ Math . 2 ] & \\ Q = \frac{1}{R} \sqrt{\frac{L}{{C}_{a}}} & ( Formula 4 )\end{matrix}$$

$$\begin{matrix}[ Math . 3 ] & \\ {k}_{vn} = \sqrt{\frac{{C}_{a}}{{C}_{a} + {C}_{b}}} & ( Formula 5 )\end{matrix}$$

[Table 1] below is a table showing the physical property values of the piezoelectric actuator. As shown in [Table 1], the input device pertaining to the present invention had a high mechanical Q factor of the piezoelectric actuator.

TABLE 1

| Physical property | Unit | Value |
|---|---|---|
| Amplitude | (V) | 0.5 |
| f₀ | (kHz) | 30.19 |
| R | (kΩ) | 0.008 |
| L | (H) | 0.001 |
| Cₐ | (nF) | 21.635 |
| C_{b} | (nF) | 1758.0 |
| Q | — | 30.57 |
| Kᵥₙ | (%) | 11.03 |
| Capacitance | (nF) | 2000 |

Description of the Symbols
100 - - - Tactile sensation generating device
110 - - - Housing
111 - - - First member
112 - - - Second member
112a - - - Joint face
120 - - - Piezoelectric actuator
121 - - - First piezoelectric actuator chip
122 - - - Second piezoelectric actuator chip
131 - - - Piezoelectric layer
132 - - - Positive internal electrode
133 - - - Negative internal electrode
141 - - - Block
142 - - - Buffer layer
150 - - - Drive part

1. A tactile sensation generating device comprising:
a housing that is constituted by a first member and a second member being joined together, and has a bar-like shape; and
a piezoelectric actuator that comprises piezoelectric layers made of piezoelectric material, positive internal electrodes provided in the piezoelectric layers, and negative internal electrodes provided in the piezoelectric layers and facing the positive internal electrodes, respectively, via the piezoelectric layers, respectively; expands/contracts along a direction perpendicular to electrode faces of the positive internal electrodes and the negative internal electrodes upon voltage application between each positive internal electrode and each negative internal electrode; is interposed between the first member and the second member in an orientation that the direction perpendicular to the electrode faces corresponds to a longitudinal direction of the housing; and is pressed by the first member and the second member along the longitudinal direction.

2. The tactile sensation generating device according to claim 1, wherein:
the first member and the second member are joined to each other by screwing together; and
the piezoelectric actuator is pressed along the longitudinal direction as a result of the screwing.

3. The tactile sensation generating device according to claim 2, wherein:
a concave part is provided in a face on a second-member side of the first member;
the tactile sensation generating device is made of metal and further has a support placed inside the concave part; and
the piezoelectric actuator is stored in the concave part and placed on the support.

4. The tactile sensation generating device according to claim 1, wherein:
the housing is pen-shaped;
the first member is a member that constitutes a pen shaft; and
the second member is a member that constitutes a pen tip.

5. The tactile sensation generating device according to claim 1, wherein:
the housing is pen-shaped; and
the first member and second member are members joined to each other to constitute a pen shaft.

6. The tactile sensation generating device according to claim 1, wherein:
the piezoelectric actuator comprises multiple piezoelectric actuator chips; and
the multiple piezoelectric actuator chips are stacked in the longitudinal direction being a stacking direction.

7. The tactile sensation generating device according to claim 1, wherein the tactile sensation generating device further has a drive part that feeds to the positive internal electrodes and the negative internal electrodes a drive signal having, when a signal wave of 2 Hz or higher but no higher than 50 Hz in frequency represents a modulation wave, a waveform resulting from amplitude-modulating a sine wave of 150 Hz or higher but no higher than 250 Hz in frequency by the modulation wave.

8. The tactile sensation generating device according to claim 1, wherein:
the housing has a prescribed resonance frequency; and
the tactile sensation generating device further has a drive part that feeds to the positive internal electrodes and negative internal electrodes a drive signal having, when a signal wave of 110 Hz or higher but no higher than 250 Hz in frequency represents a modulation wave, a waveform resulting from amplitude-modulating by the modulation wave a sine wave whose frequency corresponds to the resonance frequency.

9. The tactile sensation generating device according to claim 8, wherein the resonance frequency is 20 kHz or higher but no higher than 60 KHz.

10. The tactile sensation generating device according to claim 1, wherein:
the piezoelectric actuator comprises multiple piezoelectric actuator chips;
the piezoelectric actuator chips have a prescribed resonance frequency; and
the tactile sensation generating device further has a drive part that feeds to the positive internal electrodes and negative internal electrodes a drive signal having, when a signal wave of 110 Hz or higher but no higher than 250 Hz in frequency represents a modulation wave, a waveform resulting from amplitude-modulating by the modulation wave a sine wave whose frequency corresponds to the resonance frequency.

11. The tactile sensation generating device according to claim 10, wherein the resonance frequency is 30 kHz or higher but no higher than 110 kHz.

12. The tactile sensation generating device according to claim 1, wherein the tactile sensation generating device further has a drive part that feeds to the positive internal electrodes and negative internal electrodes a drive signal having, when a first low-frequency wave of 1 Hz or higher but lower than 60 Hz in frequency represents a first modulation wave and a waveform resulting from amplitude-modulating a second low-frequency wave of 50 Hz or higher but no higher than 300 Hz in frequency by the first modulation wave represents a second modulation wave, a waveform resulting from modulating a high-frequency wave of 20 kHz or higher but no higher than 110 kHz by the second modulation wave.

13. A tactile sensation generating system comprising:
a tactile sensation generating device comprising: a housing that is constituted by a first member and a second member being joined together, and has a bar-like shape; and a piezoelectric actuator that comprises piezoelectric layers made of piezoelectric material, positive internal electrodes provided in the piezoelectric layers, and negative internal electrodes provided in the piezoelectric layers and facing the positive internal electrodes, respectively, via the piezoelectric layers, respectively; expands/contracts along a direction perpendicular to electrode faces of the positive internal electrodes and the negative internal electrodes upon voltage application between each positive internal electrode and each negative internal electrode; is interposed between the first member and the second member in an orientation that the direction perpendicular to the electrode faces corresponds to a longitudinal direction of the housing; and is pressed by the first member and the second member along the longitudinal direction; and
a drive part that feeds a drive signal to the positive internal electrodes and negative internal electrodes.

14. A method for driving a tactile sensation generating device, comprising feeding a drive signal to positive internal electrodes and negative internal electrodes of a piezoelectric actuator installed in a housing that is constituted by a first member and a second member being joined together, and has a bar-like shape, where the piezoelectric actuator comprises piezoelectric layers made of piezoelectric material, positive internal electrodes provided in the piezoelectric layers, and negative internal electrodes provided in the piezoelectric layers and facing the positive internal electrodes, respectively, via the piezoelectric layers, respectively; expands/contracts along a direction perpendicular to electrode faces of the positive internal electrodes and the negative internal electrodes upon voltage application between each positive internal electrode and each negative internal electrode; is interposed between the first member and the second member in an orientation that the direction perpendicular to the electrode faces corresponds to a longitudinal direction of the housing; and is pressed by the first member and the second member along the longitudinal direction.
